(19) United States
(12) Patent Application Publication
(10) Pub. No.: US 2024/0097008 A1
(43) Pub. Date: Mar. 21, 2024

(54) SEMICONDUCTOR DEVICE AND METHOD OF MANUFACTURING SEMICONDUCTOR DEVICE

(71) Applicant: ROHM CO., LTD., Kyoto (JP)

(72) Inventors: Kazuhiro TAMURA, Kyoto (JP); Naoki IZUMI, Kyoto (JP); Hajime OKUDA, Kyoto (JP)

(73) Assignee: ROHM CO., LTD., Kyoto (JP)

(21) Appl. No.: 18/462,728

(22) Filed: Sep. 7, 2023

(30) Foreign Application Priority Data
Sep. 16, 2022 (JP) 2022-148387

(51) Int. Cl. H01L 29/66; H01L 29/08; H01L 29/78

(52) U.S. Cl. CPC H01L 29/66681; H01L 29/086; H01L 29/0878; H01L 29/7824

(57) ABSTRACT

A semiconductor device includes: an n-type semiconductor layer; a p-type drift region formed in a surface layer of the n-type semiconductor layer; an n-type body region formed in the surface layer of the n-type semiconductor layer so as to be spaced apart from or adjacent to the p-type drift region; a p-type drain region formed in a surface layer of the p-type drift region; a p-type source region formed in a surface layer of the n-type body region; a gate insulating film formed over a surface of the n-type semiconductor layer so as to straddle the p-type drift region and the n-type body region; a gate electrode formed over the gate insulating film; and an n-type region formed in the surface layer of the p-type drift region and arranged between a side edge of the p-type drift region near the n-type body region and the p-type drain region.

### CROSS-REFERENCE TO RELATED APPLICATION

This application is based upon and claims the benefit of priority from Japanese Patent Application No. 2022-148387, filed on Sep. 16, 2022, the entire contents of which are incorporated herein by reference.

### TECHNICAL FIELD

The present disclosure relates to a semiconductor device, and a method of manufacturing a semiconductor device.

### BACKGROUND

In the related art, there is known a DMOSFET (Double Diffused Metal Oxide Semiconductor Field Effect Transistor) that includes a deep n-well formed over a silicon substrate, a p-type region formed in a surface layer of the deep n-well, an n-type well formed in the surface layer of the deep n-well with a gap from the p-type region, a p-type drain region formed in a surface layer of the p-type region, a p-type source region formed in a surface layer of the n-type well, a gate insulating film formed over the surface of the deep n-well so as to straddle the p-type region and the n-type well, and a gate electrode formed over the gate insulating film. In the related art, the p-type region includes a p-type drift layer and a p-type well.

### BRIEF DESCRIPTION OF DRAWINGS

The accompanying drawings, which are incorporated in and constitute a part of the specification, illustrate embodiments of the present disclosure.

FIG. 1 is a schematic partial cross-sectional view showing a structure of a main part of a semiconductor device according to an embodiment of the present disclosure.

FIG. 2 is a schematic partial cross-sectional view showing a structure of a main part of a semiconductor device according to an embodiment of the present disclosure ion, and is different from FIG. 1 in a Y-directional position.

FIG. 3A is a cross-sectional view showing an example of a manufacturing process of the semiconductor device shown in FIGS. 1 and 2, and is a cross-sectional view corresponding to a cross section of FIG. 1.

FIG. 3B is a cross-sectional view showing a next step of FIG. 3A.

FIG. 3C is a cross-sectional view showing a next step of FIG. 3B.

FIG. 3D is a cross-sectional view showing a next step of FIG. 3C.

FIG. 3E is a cross-sectional view showing a next step of FIG. 3D.

FIG. 3F is a cross-sectional view showing a next step of FIG. 3E.

FIG. 3G is a cross-sectional view showing a next step of FIG. 3F.

FIG. 3H is a cross-sectional view showing a next step of FIG. 3G.

FIG. 3I is a cross-sectional view showing a next step of FIG. 3H.

FIG. 3J is a cross-sectional view showing a next step of FIG. 3I.

FIG. 3K is a cross-sectional view showing a next step of FIG. 3J.

FIG. 3L is a cross-sectional view showing a next step of FIG. 3K.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

An embodiment of the present disclosure will now be described in detail with reference to the accompanying drawings.

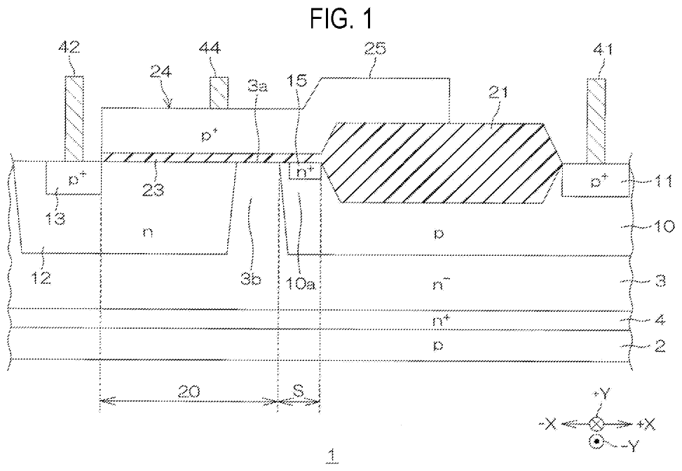

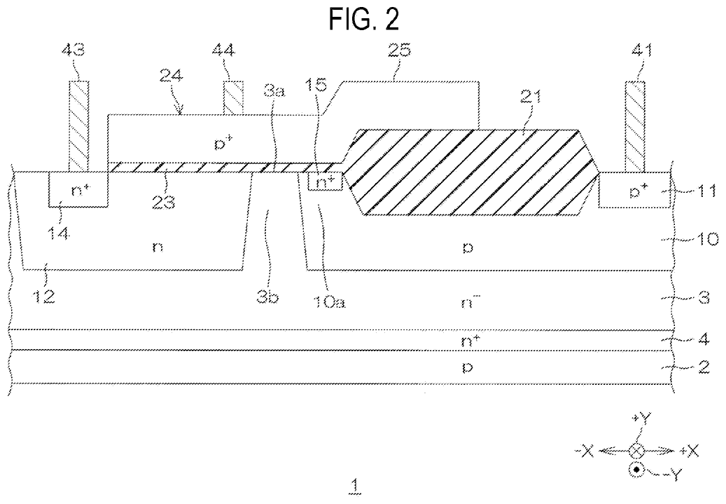

FIG. 1 is a schematic partial cross-sectional view showing a structure of a main part of a semiconductor device according to an embodiment of the present disclosure. FIG. 2 is a schematic partial cross-sectional view showing a structure of a main part of a semiconductor device according to an embodiment of the present disclosure, and is a cross-sectional view different from FIG. 1 in a Y-directional position.

For the sake of convenience of description, +X direction, —X direction, +Y direction, and −Y direction shown in FIGS. 1 and 2 may be used hereinafter. The +X direction is a predetermined direction along a surface of a semiconductor substrate 2 in a plan view, and the +Y direction is a direction along the surface of the semiconductor substrate 2 in the plan view and perpendicular to the +X direction. The —X direction is a direction opposite the +X direction. The −Y direction is a direction opposite the +Y direction. The +X direction and the —X direction are collectively and simply referred to as “X direction.” The +Y direction and the −Y direction are collectively and simply referred to as “Y direction.”

In the present embodiment, the semiconductor device 1 is a p-channel LDMOSFET (Lateral Double Diffused Metal Oxide Semiconductor Field Effect Transistor).

The semiconductor device 1 includes a semiconductor substrate 2 and an epitaxial layer 3 formed on the semiconductor substrate 2. The semiconductor device 1 includes an embedded layer 4 selectively formed across the semiconductor substrate 2 and the epitaxial layer 3 at a boundary between the semiconductor substrate 2 and the epitaxial layer 3. Although not shown in FIGS. 1 and 2, the epitaxial layer 3 is in contact with a surface of the semiconductor substrate 2 at a location where the embedded layer 4 is not formed.

The semiconductor substrate 2 is constituted by a silicon (Si) substrate in the present embodiment. The semiconductor substrate 2 may be a substrate other than the silicon substrate, such as a silicon carbide (SiC) substrate or the like. The semiconductor substrate 2 is p-type in the present embodiment. The semiconductor substrate 2 has an impurity concentration of, for example, 1×10¹⁴ cm⁻³ to 5×10¹⁸ cm⁻³. In the present embodiment, a p-type impurity concentration of the semiconductor substrate 2 is about 1.5×10¹⁵ cm⁻³. A thickness of the semiconductor substrate 2 is, for example, 500 μm to 800 μm before polishing.

The epitaxial layer 3 has an element main surface 3a on a side opposite the semiconductor substrate 2. The epitaxial layer 3 is an example of the “semiconductor layer” of the present disclosure. The epitaxial layer 3 is made of silicon (Si) in the present embodiment. The epitaxial layer 3 may be made of a material other than silicon, such as silicon carbide (SiC) or the like. The epitaxial layer 3 is n-type. As the n-type impurity, for example, P (phosphorus), As (arsenic), Sb (antimony), or the like may be applied (the same applies hereinafter).

The n-type impurity concentration of the epitaxial layer 3 is, for example, about 5×10¹⁴ cm⁻³ to 1×10¹⁷ cm⁻³. In the present embodiment, the n-type impurity concentration of the epitaxial layer 3 is about 4×10¹⁴ cm⁻³. The film thickness of the epitaxial layer 3 is, for example, 3 μm to 20 μm. In the present embodiment, the thickness of the epitaxial layer 3 is about 10 μm.

The embedded layer 4 is n-type. An n-type impurity concentration of the embedded layer 4 is higher than that of the epitaxial layer 3. The film thickness of the embedded layer 4 is, for example, 2 μm to 10 μm. In the present embodiment, the film thickness of the embedded layer 4 is about 5 μm.

A p-type drift region 10 is formed in a surface layer of the epitaxial layer 3 near the element main surface 3a. The drift region 10 includes a quadrangular portion extending in the Y direction in a plan view. As a p-type impurity, for example, B (boron), Al (aluminum), Ga (gallium), or the like may be applied (the same applies hereinafter). The p-type impurity concentration of the drift region 10 is, for example, 5.0×10¹⁵ cm⁻³ to 2.0×10¹⁶ cm⁻³. In the present embodiment, the p-type impurity concentration of the drift region 10 is 1.0×10¹⁶ cm⁻³.

A p-type drain region 11 having a p-type impurity concentration higher than that of the drift region 10 is formed in the surface layer of the drift region 10. The drain region 11 is formed in a quadrangular shape elongated in the Y direction in a plan view.

An n-type body region 12 is formed in the surface layer of the epitaxial layer 3 near the element main surface 3a so as to be spaced apart from the drift region 10. In FIGS. 1 and 2, the body region 12 is arranged on the −X side with respect to the drift region 10. The body region 12 may be in contact with the drift region 10. That is, the body region 12 may be formed adjacent to the drift region 10. The body region 12 is formed in a quadrangular shape elongated in the Y direction in a plan view.

The n-type impurity concentration of the body region 12 is, for example, about 5.0×10¹⁶ cm⁻³ to 2.0×10¹⁷ cm⁻³. In the present embodiment, the n-type impurity concentration of the body region 12 is, for example, 1.0×10¹⁷ cm⁻³.

In the present embodiment, the epitaxial layer 3 exists between the body region 12 and the drift region 10 in the X direction. Hereinafter, the epitaxial layer 3 existing between the body region 12 and the drift region 10 may be referred to as a narrow portion 3b of the epitaxial layer 3 below.

A p-type source region 13 (see FIG. 1) having a p-type impurity concentration higher than that of the drift region 10 and an n-type body contact region 14 (see FIG. 2) having an n-type impurity concentration higher than that of the body region 12 are formed in the surface layer of the body region 12 so as to be alternately arranged in the Y direction.

A channel region 20 is a region between the source region 13 and the drift region 10 in the body region 12 and the surface layer of the narrow portion 3b of the epitaxial layer 3. The channel region 20 is a region in which conduction and non-conduction between a drain and a source are controlled.

A field insulating film 21 selectively covering the drift region 10 is formed on the element main surface 3a of the epitaxial layer 3. In the present embodiment, the field insulating film 21 is constituted by a LOCOS (Local Oxidation of Silicon) oxide film.

In FIGS. 1 and 2, the side edge of the field insulating film 21 near the body region 12 is located on the +X side of the side edge of the drift region 10 near the body region 12. Hereinafter, in a plan view, a portion of the drift region 10 closer to the body region 12 than the side edge of the field insulating film 21 near the body region 12 may be referred to as a channel-side region 10a of the drift region 10.

The side edge of the field insulating film 21 opposite the side edge of the field insulating film 21 near the body region 12 coincides with the —X-side edge of the drain region 11.

A gate insulating film 23 is formed over the element main surface 3a of the epitaxial layer 3 between the source region 13 and the field insulating film 21. The +X-side edge of the gate insulating film 23 is connected to the —X-side edge of the field insulating film 21. The gate insulating film 23 is formed across the drift region 10 and the body region 12. The gate insulating film 23 preferably includes a silicon oxide film.

The gate insulating film 23 has a thickness smaller than that of the field insulating film 21. The gate electrode 24 includes a quadrangular portion extending in the Y direction in a plan view. The gate insulating film 23 covers the channel region 20 and the channel-side region 10a of the drift region 10. Specifically, the gate insulating film 23 covers the portion of the body region 12 closer to the drift region 10 than the source region 13 (body contact region 14), the narrow portion 3b of the epitaxial layer 3, and the channel-side region 10a of the drift region 10.

A gate electrode 24 is formed over the gate insulating film 23. In the present embodiment, the gate electrode 24 contains conductive polysilicon. Such a gate electrode 24 may be referred to as a “poly-gate” or “poly-silicon gate.” In the present embodiment, the gate electrode 24 is made of polysilicon containing a p-type impurity.

The gate electrode 24 faces the channel region 20 and the channel-side region 10a of the drift region 10 via the gate insulating film 23. Specifically, the gate electrode 24 faces the portion of the body region 12 closer to the drift region 10 than the source region 13 (body contact region 14), the narrow portion 3b of the epitaxial layer 3, and the channel-side region 10a of the drift region 10, via the gate insulating film 23.

In the present embodiment, the gate electrode 24 includes a lead-out portion 25 that is led out from above the gate insulating film 23 to above the field insulating film 21. The lead-out portion 25 is formed so as to be spaced apart from the drain region 11 toward the edge of the drift region 10 near the body region 12 in a plan view, and faces the drift region 10 via the field insulating film 21.

An n-type region 15 is formed in the surface layer of the drift region 10 between the side edge of the drift region 10 near the body region 12 and the drain region 11. The N-type region 15 is formed so as to be spaced apart from the drain region 11.

In the present embodiment, an n-type region 15 is formed in a region S (channel-side region 10a), which is a region in the surface layer of the drift region 10 and is defined between the side edge of the drift region 10 near the body region 12 and the field insulating film 21. The n-type region 15 is preferably formed so as to be spaced apart from the side edge of the drift region 10 near the body region 12. The side edge of the n-type region 15 near the drain region 11 may be located closer to the drain region 11 than the side edge of the field insulating film 21 near the body region 12.

The n-type region 15 has an n-type impurity concentration higher than that of the epitaxial layer 3 and lower than that of the body region 12. The n-type impurity concentration of the n-type region 15 is, for example, 2.5×10¹⁵ cm⁻³ to 1.0×10¹⁶ cm⁻³. In the present embodiment, the n-type impurity concentration of the n-type region 15 is, for example, 5.0×10¹⁵ cm⁻³. The reason that the n-type region 15 is formed in the surface layer of the drift region 10 will be described later.

The semiconductor device 1 includes a plurality of drain contact electrodes 41, a plurality of source contact electrodes 42, a plurality of body contact electrodes 43, and a plurality of gate contact electrodes 44.

The drain contact electrodes 41 are arranged at intervals in the Y direction. Each drain contact electrode 41 is electrically connected to the drain region 11. The drain contact electrodes 41 apply a drain potential Vd to the drain region 11.

The source contact electrodes 42 are arranged at intervals in the Y direction. Each source contact electrode 42 is electrically connected to the source region 13. The source contact electrodes 42 apply a source potential Vs to the source region 13.

The body contact electrodes 43 are arranged at intervals in the Y direction. Each body contact electrode 43 is electrically connected to the body contact region 14. The body contact electrodes 43 apply a source potential Vs to the body contact region 14.

The gate contact electrodes 44 are arranged at intervals in the Y direction. Each gate contact electrode 44 is electrically connected to the gate electrode 24. The gate contact electrodes 44 apply a gate potential Vg to the gate electrode 24.

The semiconductor device 1 is configured to allow a drain/source current to flow during an on operation. During the on operation, the source region 13 is applied with a source potential Vs (for example, Vs=0 V), the drain region 11 is applied with a drain potential Vd (for example, Vd=−80 V), and the gate electrode 24 is applied with a gate potential Vg (for example, Vd=−1.5 V).

Hereinafter, a semiconductor device in which the n-type region 15 is not formed in the drift region 10 in the semiconductor device 1 of FIG. 1 will be referred to as a comparative example.

It was found that the gate insulating film 23 may be damaged in the comparative example. In the comparative example, during an on operation, electrons are accelerated by a voltage applied between a source and a drain, and collide with atoms to generate electron (hot electron)-hole pairs. That is, the electron-hole pairs are generated in the drift region 10 by impact ionization. The impact ionization tends to occur near a boundary with the n-type epitaxial layer 3 in the drift region 10 where the electric field tends to concentrate. When the body region 12 is formed so as to contact the drift region 10, the impact ionization is likely to occur near the boundary with the body region 12 in the drift region 10.

An interface state is formed at the interface between the gate insulating film 23 and the epitaxial layer 3 by the electron-hole pairs generated by the impact ionization. When the interface state is formed, electrons are trapped in the interface state. A strong electric field is generated in the gate insulating film 34 by the electrons trapped in the interface state, and the gate insulating film 34 is damaged. This increases a gate leakage current.

In the present embodiment, in the surface layer of the drift region 10, the n-type region 15 is formed between the side edge of the drift region 10 near the body region 12 and the drain region 11. Therefore, it is possible to suppress damage to the gate insulating film 23. The reason for this will be described below.

As the p-type impurity concentration in the drift region becomes higher, the impact ionization is more likely to occur. In the present embodiment, since the n-type region 15 is formed in the drift region 10, the p-type impurity concentration is low in the region where the n-type region 15 is formed. This reduces an impact ionization rate and suppresses generation of hot electrons. As a result, it is possible to reduce the number of electrons trapped in the gate insulating film 23, thereby suppressing damage to the gate insulating film 23.

The n-type region 15 is preferably formed in a region within the drift region 10 where the impact ionization is likely to occur. Therefore, in the present embodiment, the n-type region 15 is formed in the surface layer of the drift region 10 and in the region between the side edge of the drift region 10 near the body region 12 and the field insulating film 21.

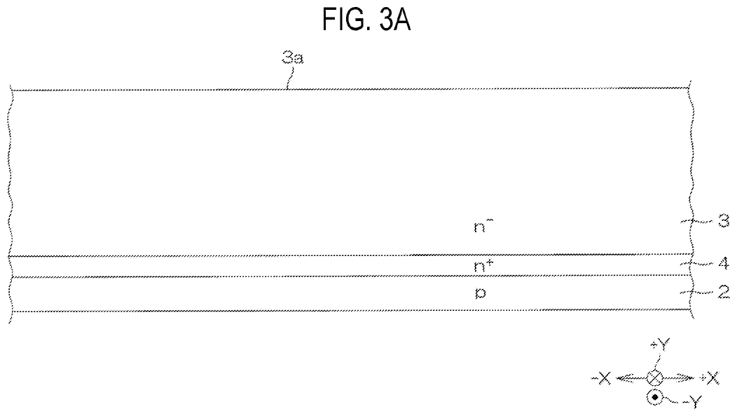

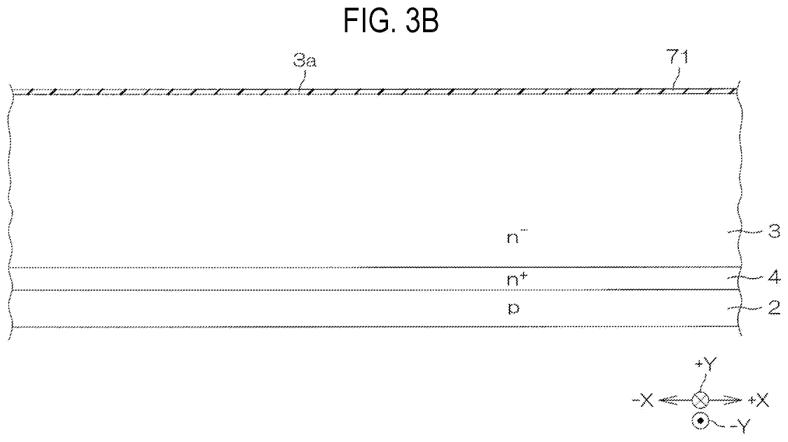

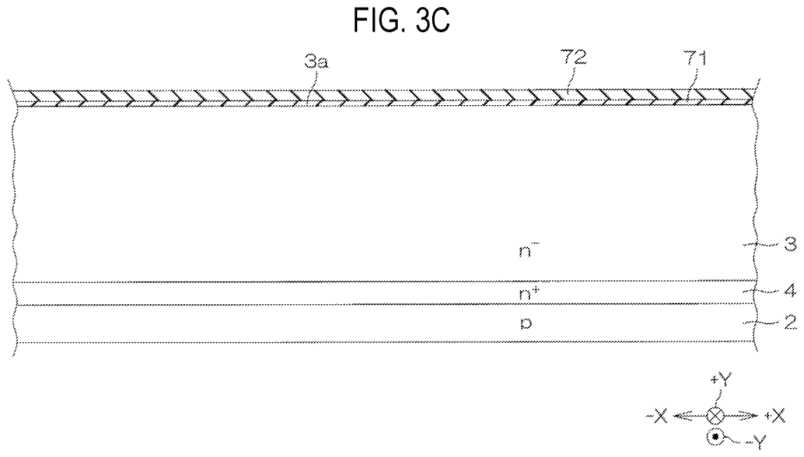

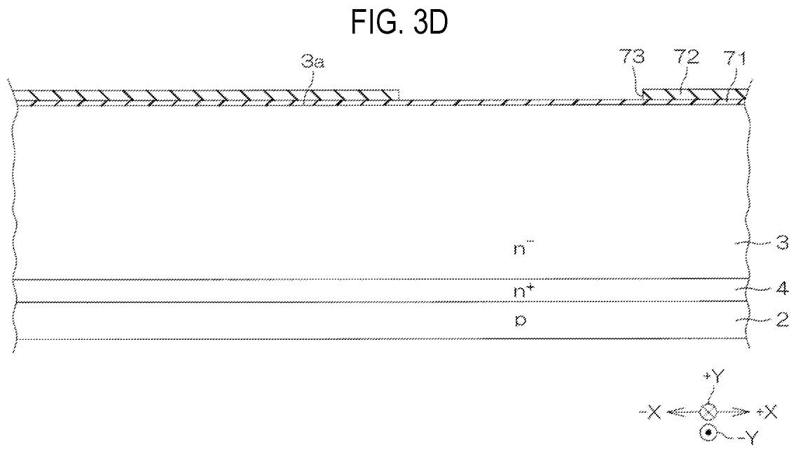

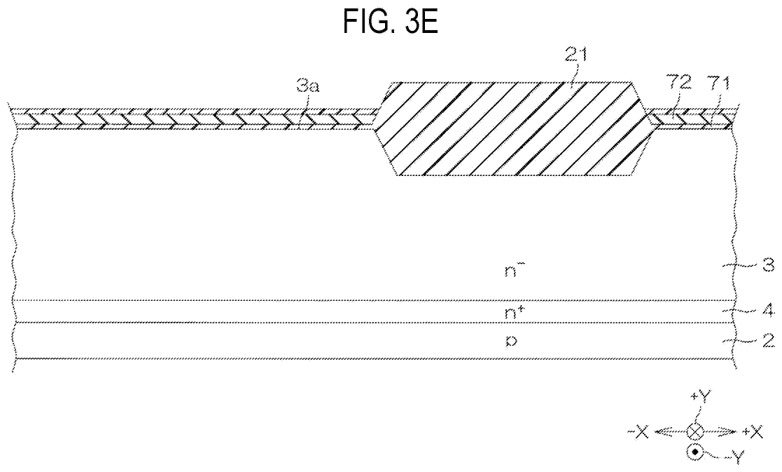

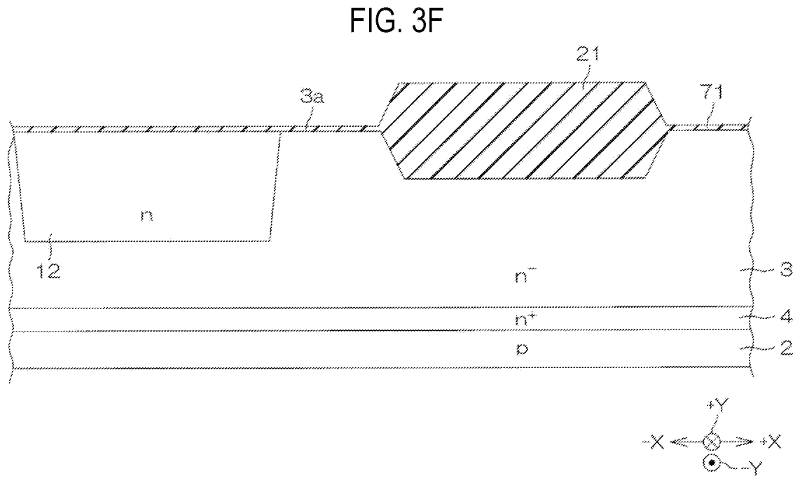

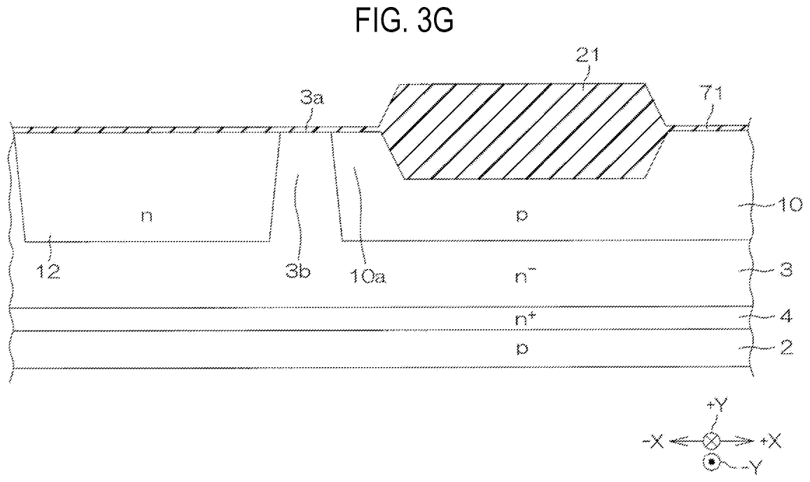

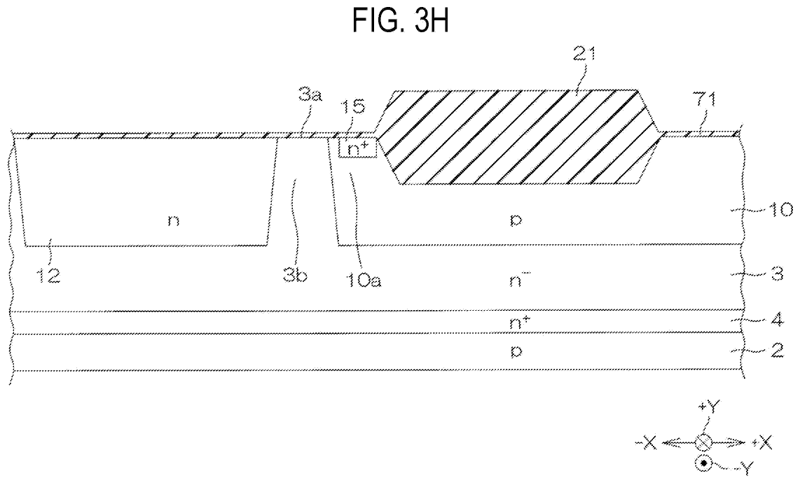

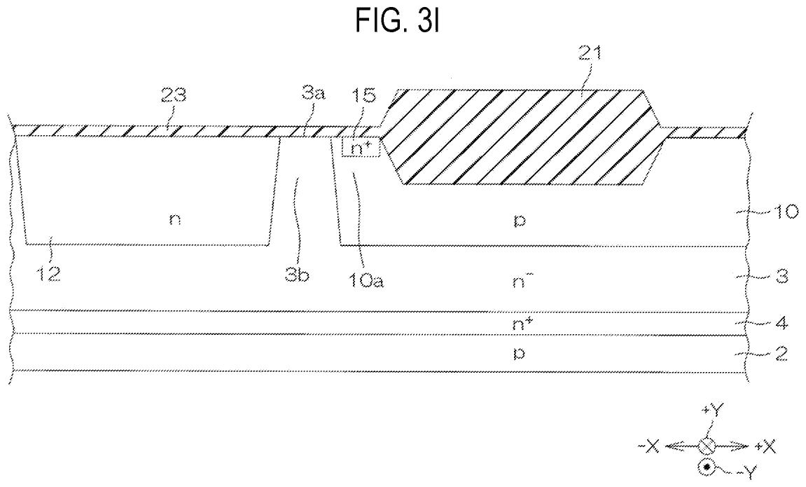

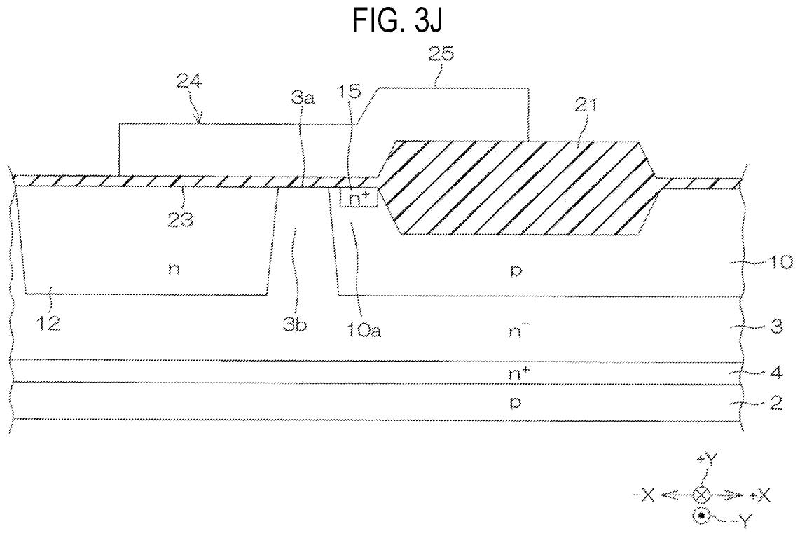

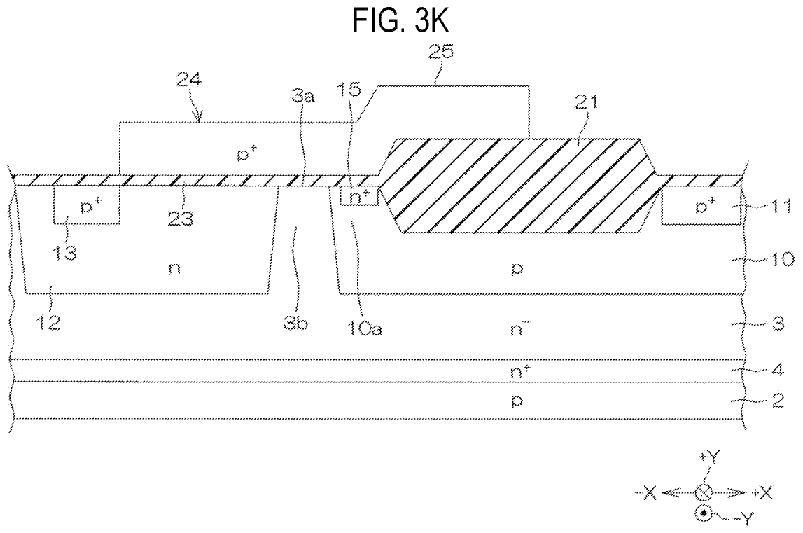

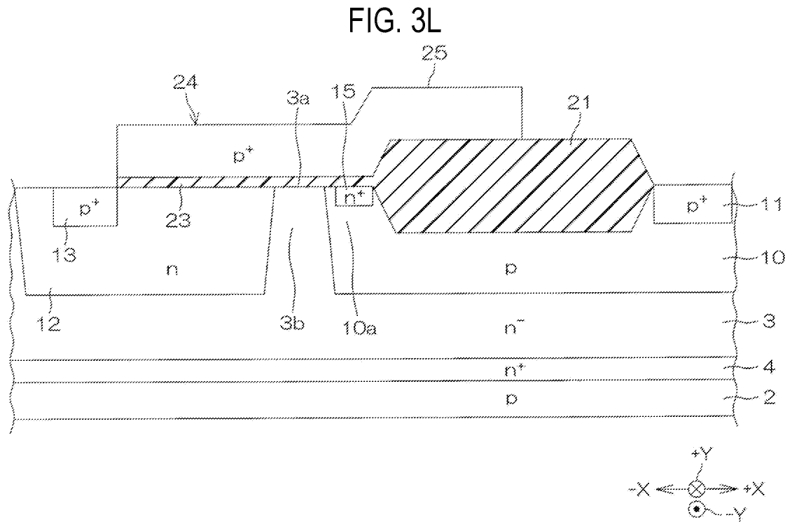

A manufacturing process of the semiconductor device 1 shown in FIG. 1 will be described with reference to FIGS. 3A to 3L. FIGS. 3A to 3L are cross-sectional views for explaining an example of the manufacturing process of the semiconductor device 1, and are cross-sectional views corresponding to the cross section of FIG. 1.

First, a p-type semiconductor substrate 2 is prepared. Next, an n-type impurity is selectively implanted into the surface of the semiconductor substrate 2 to form an n-type embedded layer 4. Then, under a heating condition of, for example, 1,100 degrees C. or higher, silicon is epitaxially grown on the semiconductor substrate 2 while adding an n-type impurity. Thus, an n-type epitaxial layer 3 is formed over the semiconductor substrate 2 as shown in FIG. 3A.

When the epitaxial layer 3 grows, the n-type impurity implanted into the semiconductor substrate 2 diffuses in a growth direction of the epitaxial layer 3. As a result, an n-type embedded layer 4 straddling the boundary between the semiconductor substrate 2 and the epitaxial layer 3 is formed.

Next, as shown in FIG. 3B, a base insulating film 71 (having a thickness of, e.g., 5 nm to 50 nm) is formed over the element main surface 3a of the epitaxial layer 3 by, for example, a method such as thermal oxidation or the like. The base insulating film 71 is made of silicon oxide (SiO₂) in the present embodiment.

Next, as shown in FIG. 3C, a mask insulating film 72 (having a thickness of, e.g., 80 nm to 200 nm) is deposited on the base insulating film 71 by, for example, a method such as a low pressure CVD method or the like. The mask insulating film 72 is made of silicon nitride (SiN) in the present embodiment.

Next, as shown in FIG. 3D, by photolithography and etching, an opening 73 is formed in a region of the mask insulating film 72 facing the region where the field insulating film 21 is formed.

Next, as shown in FIG. 3E, by thermally oxidizing the portion of the epitaxial layer 3 exposed from the opening 73 of the mask insulating film 72, the base insulating film 71 is thickened, and a field insulating film 21 constituted by a LOCOS oxide film is formed in the surface layer of the epitaxial layer 3 near the element main surface 3a.

Next, as shown in FIG. 3F, the mask insulating film 72 is removed, for example, by etching with hydrogen fluoride water or the like. Thereafter, an n-type body region 12 is formed in the surface layer of the epitaxial layer 3 near the element main surface 3a. For forming the body region 12, first, an ion implantation mask (not shown), which has an opening selectively formed, is formed in a region where the body region 12 is to be formed. Then, an n-type impurity is implanted into the epitaxial layer 3 through the ion implantation mask. Thus, the body region 12 is formed. Thereafter, the ion implantation mask is removed.

Next, as shown in FIG. 3G, a p-type drift region 10 is formed in the surface layer of the epitaxial layer 3 near the element main surface 3a. For forming the drift region 10, first, an ion implantation mask (not shown), which has an opening selectively formed, is formed in a region where the drift region 10 is to be formed. Then, a p-type impurity is implanted into the epitaxial layer 3 through the ion implantation mask. Thus, the drift region 10 is formed. Thereafter, the ion implantation mask is removed.

Next, as shown in FIG. 3H, an n-type region 15 is formed in the surface layer of the drift region 10. When forming the n-type region 15, first, an ion implantation mask (not shown), which has an opening selectively formed, is formed in a region where the n-type region 15 is to be formed. Then, an n-type impurity is implanted into the drift region 10 through the ion implantation mask. Thus, the n-type region 15 is formed. Thereafter, the ion implantation mask is removed.

Next, as shown in FIG. 3I, surfaces of the base insulating film 71 and the field insulating film 21 are thermally oxidized. As a result, the base insulating film 71 is thickened and a gate insulating film 23 is formed.

Next, polysilicon is deposited on the entire element main surface 3a of the epitaxial layer 3 by, for example, a low-pressure CVD method or the like. Thereafter, as shown in FIG. 3J, a gate electrode 24 made of polysilicon is formed by going through a photolithography process.

Next, an n-type body contact region 14 (see FIG. 2) is formed in the surface layer of the body region 12. When forming the body contact region 14, first, an ion implantation mask (not shown), which has an opening selectively formed, is formed in a region where the body contact region 14 is to be formed. Then, an n-type impurity is implanted into the body region 12 through the ion implantation mask. Thus, the body contact region 14 is formed. Thereafter, the ion implantation mask is removed.

Next, as shown in FIG. 3K, a p-type source region 13 is formed in the surface layer of the body region 12, a p-type drain region 11 is formed in the surface layer of the drift region 10, and a gate electrode 24 made of polysilicon containing a p-type impurity is formed.

For forming the source region 13, the drain region 11, and the gate electrode 24 made of polysilicon containing a p-type impurity, first, an ion implantation mask (not shown), which has openings selectively formed, is formed in a region where the source region 13 and the drain region 11 are to be formed and in a region of the gate electrode 24 where the p-type impurity is to be implanted. Then, a p-type impurity is implanted into the body region 12, the drift region 10, and the gate electrode 24 through the ion implantation mask. As a result, the source region 13 and the drain region 11 are formed, and the gate electrode 24 made of polysilicon containing a p-type impurity is formed. Thereafter, the ion implantation mask is removed.

Next, as shown in FIG. 3L, a hard mask (not shown) having an opening selectively formed to remove an unnecessary portion of the gate insulating film 23 is formed over the epitaxial layer 3. Then, the unnecessary portion of the gate insulating film 23 is etched through the hard mask. Thus, a predetermined gate insulating film 23 is formed. As a result, the surfaces of the drain region 11, the source region 13, and the body contact region 14 are exposed. Thereafter, the hard mask is removed.

Finally, a plurality of drain contact electrodes 41 electrically connected to the drain region 11, a plurality of source contact electrodes 42 electrically connected to the source region 13, a plurality of body contact electrodes 43 electrically connected to the body contact region 14, and a plurality of gate contact electrodes 44 electrically connected to the gate electrodes 18 are formed. Thus, the semiconductor device 1 shown in FIGS. 1 and 2 is obtained.

In the above-described embodiments, the body contact region 14, the source region 13, and the drain region 11 are formed after the gate electrode 24 is formed in FIG. 3J. Alternatively, the body contact region 14, the source region 13 and the drain region 11 may be formed before the gate electrode 24 is formed.

Although the embodiments of the present disclosure have been described in detail above, the embodiments are merely specific examples used to clarify technical contents of the present disclosure. The present disclosure should not be construed to be limited to those specific examples. The scope of the present disclosure is limited only by the appended claims.

The features described as supplementary notes below may be extracted from the description in the specification and drawings of the present disclosure.

[Supplementary Note 1-1] A semiconductor device comprising: an n-type semiconductor layer (3); a p-type drift region (10) formed in a surface layer of the n-type semiconductor layer (3); an n-type body region (12) formed in the surface layer of the n-type semiconductor layer (3) so as to be spaced apart from or adjacent to the drift region (10); a p-type drain region (11) formed in a surface layer of the p-type drift region (10); a p-type source region (13) formed in a surface layer of the n-type body region (12); a gate insulating film (23) formed over a surface of the n-type semiconductor layer (3) so as to straddle the p-type drift region (10) and the n-type body region (12); a gate electrode (24) formed over the gate insulating film (23); and an n-type region (15) formed in the surface layer of the p-type drift region (10) and arranged between a side edge of the p-type drift region (10) near the n-type body region (12) and the p-type drain region (11).

[Supplementary Note 1-2] The semiconductor device of Supplementary Note 1-1, wherein the n-type region (15) is formed so as to be spaced apart from the side edge of the p-type drift region (10) near the n-type body region (12).

[Supplementary Note 1-3] The semiconductor device of Supplementary Note 1-1, wherein a field insulating film (21) selectively covering the p-type drift region (10) and connected to the gate insulating film (23) is formed over the surface of the n-type semiconductor layer (3) between the gate insulating film (23) and the p-type drain region (11), and the n-type region (15) is formed in a region (S) which is defined between the side edge of the p-type drift region (10) near the n-type body region (12) and the field insulating film (23) and is spaced apart from the side edge.

[Supplementary Note 1-4] The semiconductor device of Supplementary Note 1-3, wherein a thickness of the gate insulating film (23) is smaller than a thickness of the field insulating film (21).

[Supplementary Note 1-5] The semiconductor device of any one of Supplementary Notes 1-1 to 1-4, wherein the gate insulating film (23) includes a silicon oxide film.

[Supplementary Note 1-6] The semiconductor device of Supplementary Note 1-3, wherein the field insulating film (21) includes a LOCOS film.

[Supplementary Note 1-7] The semiconductor device of any one of Supplementary Notes 1-1 to 1-6, wherein an n-type impurity concentration of the n-type body region (12) is higher than an n-type impurity concentration of the n-type semiconductor layer (3), and wherein an n-type impurity concentration of the n-type region (15) is higher than the n-type impurity concentration of the n-type semiconductor layer (3) and lower than the n-type impurity concentration of the n-type body region (12).

[Supplementary Note 1-8] The semiconductor device of any one of Supplementary Notes 1-1 to 1-7, wherein the gate electrode (24) is made of polysilicon containing an impurity.

[Supplementary Note 1-9] The semiconductor device of any one of Supplementary Notes 1-1 to 1-8, further comprising an n-type body contact region (14) formed in the surface layer of the n-type body region (12).

[Supplementary Note 1-10] The semiconductor device of any one of Supplementary Notes 1-1 to 1-9, wherein a p-type impurity concentration of the p-type drift region (10) is 5.0×10¹⁵ cm⁻³ to 2.0×10¹⁶ cm⁻³, and an n-type impurity concentration of the n-type region (15) is 2.5×10¹⁵ cm⁻³ to 1.0×10¹⁶ cm⁻³.

[Supplementary Note 1-11] A method of manufacturing a semiconductor device, comprising: forming an n-type body region (12) and a p-type drift region (10) in a surface layer of an n-type semiconductor layer (3) such that the n-type body region (12) and the p-type drift region (10) are spaced apart from each other or adjacent to each other; forming a gate insulating film (23) over a surface of the n-type semiconductor layer (3) such that the gate insulating film (23) straddles the n-type body region (12) and the p-type drift region (10); forming an n-type region (15) in a surface layer of the p-type drift region (10); forming a gate electrode (24) over the gate insulating film (23); forming a p-type source region (13) in a surface layer of the n-type body region (12); and forming a p-type drain region (11) in the surface layer of the p-type drift region (10), wherein the n-type region (15) is formed between a side edge of the p-type drift region (10) near the n-type body region (12) and the p-type drain region (11).

[Supplementary Note 1-12] The method of Supplementary Note 1-11, wherein the n-type region (15) is formed so as to be spaced apart from the side edge of the p-type drift region (10) near the n-type body region (12).

[Supplementary Note 1-13] The method of Supplementary Note 1-11, further comprising: forming a field insulating film (21) selectively covering the p-type drift region (10) and connected to the gate insulating film (23) over the surface of the n-type semiconductor layer (3) between the gate insulating film (23) and the p-type drain region (11), wherein the n-type region (15) is formed in a region (S) which is defined between the side edge of the p-type drift region (10) near the n-type body region (12) and the field insulating film (23) and is spaced apart from the side edge.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
an n-type semiconductor layer;
a p-type drift region formed in a surface layer of the n-type semiconductor layer;
an n-type body region formed in the surface layer of the n-type semiconductor layer so as to be spaced apart from or adjacent to the p-type drift region;
a p-type drain region formed in a surface layer of the p-type drift region;
a p-type source region formed in a surface layer of the n-type body region;
a gate insulating film formed over a surface of the n-type semiconductor layer so as to straddle the p-type drift region and the n-type body region;
a gate electrode formed over the gate insulating film; and
an n-type region formed in the surface layer of the p-type drift region and arranged between a side edge of the p-type drift region near the n-type body region and the p-type drain region.

2. The semiconductor device of claim 1, wherein the n-type region is formed so as to be spaced apart from the side edge of the p-type drift region near the n-type body region.

3. The semiconductor device of claim 1, wherein a field insulating film selectively covering the p-type drift region and connected to the gate insulating film is formed over the surface of the n-type semiconductor layer between the gate insulating film and the p-type drain region, and
wherein the n-type region is formed in a region which is defined between the side edge of the p-type drift region near the n-type body region and the field insulating film and is spaced apart from the side edge.

4. The semiconductor device of claim 3, wherein a thickness of the gate insulating film is smaller than a thickness of the field insulating film.

5. The semiconductor device of claim 3, wherein the gate insulating film includes a silicon oxide film.

6. The semiconductor device of claim 3, wherein the field insulating film includes a LOCOS film.

7. The semiconductor device of claim 1, wherein an n-type impurity concentration of the n-type body region is higher than an n-type impurity concentration of the n-type semiconductor layer, and
wherein an n-type impurity concentration of the n-type region is higher than the n-type impurity concentration of the n-type semiconductor layer and lower than the n-type impurity concentration of the n-type body region.

8. The semiconductor device of claim 1, wherein the gate electrode is made of polysilicon containing an impurity.

9. The semiconductor device of claim 1, further comprising an n-type body contact region formed in the surface layer of the n-type body region.

10. The semiconductor device of claim 1, wherein a p-type impurity concentration of the p-type drift region is 5.0×10¹⁵ cm⁻³ to 2.0×10¹⁶ cm⁻³, and an n-type impurity concentration of the n-type region is 2.5×10¹⁵ cm⁻³ to 1.0×10¹⁶ cm⁻³.

11. A method of manufacturing a semiconductor device, comprising:
forming an n-type body region and a p-type drift region in a surface layer of an n-type semiconductor layer such that the n-type body region and the p-type drift region are spaced apart from each other or adjacent to each other;
forming a gate insulating film over a surface of the n-type semiconductor layer such that the gate insulating film straddles the n-type body region and the p-type drift region;
forming an n-type region in a surface layer of the p-type drift region;
forming a gate electrode over the gate insulating film;
forming a p-type source region in a surface layer of the n-type body region; and
forming a p-type drain region in the surface layer of the p-type drift region,
wherein the n-type region is formed between a side edge of the p-type drift region near the n-type body region and the p-type drain region.

12. The method of claim 11, wherein the n-type region is formed so as to be spaced apart from the side edge of the p-type drift region near the n-type body region.

13. The method of claim 11, further comprising:
forming a field insulating film selectively covering the p-type drift region and connected to the gate insulating film over the surface of the n-type semiconductor layer between the gate insulating film and the p-type drain region,
wherein the n-type region is formed in a region which is defined between the side edge of the p-type drift region near the n-type body region and the field insulating film and is spaced apart from the side edge.
